(19) United States
(12) Patent Application Publication
(10) Pub. No.: US 2014/0315371 A1
(43) Pub. Date: Oct. 23, 2014

(54) METHODS OF FORMING ISOLATION REGIONS FOR BULK FINFET SEMICONDUCTOR DEVICES

(71) Applicants: GLOBALFOUNDRIES INC., Grand Cayman (KY); INTERNATIONAL BUSINESS MACHINES CORPORATION, Armonk, NY (US)

(72) Inventors: Xiuyu Cai, Niskayuna, NY (US); Ruilong Xie, Niskayuna, NY (US); Kangguo Cheng, Schenectady, NY (US); Ali Khakifirooz, Mountain View, CA (US)

(73) Assignees: International Business Machines Corporation, Armonk, CA (US); Globalfoundries Inc., Grand Cayman (KY)

(21) Appl. No.: 13/864,420

(22) Filed: Apr. 17, 2013

(51) Int. Cl. H01L 29/66; H01L 21/762

(52) U.S. Cl. CPC H01L 29/66795; H01L 21/76224
USPC 438/424

(57) ABSTRACT

One method disclosed herein includes forming a plurality of fin-formation trenches in a semiconductor substrate that define a plurality of spaced-apart fins, forming a patterned liner layer that covers a portion of the substrate positioned between the fins while exposing portions of the substrate positioned laterally outside of the patterned liner layer, and performing at least one etching process on the exposed portions of the substrate through the patterned liner layer to define an isolation trench in the substrate, wherein the isolation trench has a depth that is greater than a depth of the fin-formation trenches.

### BACKGROUND OF THE INVENTION

1. Field of the Invention

Generally, the present disclosure relates to the manufacture of semiconductor devices, and, more specifically, to various methods of forming isolation regions for 3D semiconductor devices, such as FinFET devices.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide field effect transistors (MOSFETs or FETs) represent one important type of circuit element that substantially determines performance of the integrated circuits. A FET is a planar device that typically includes a source region, a drain region, a channel region that is positioned between the source region and the drain region, and a gate electrode positioned above the channel region. Current flow through the FET is controlled by controlling the voltage applied to the gate electrode. If there is no voltage applied to the gate electrode, then there is no current flow through the device (ignoring undesirable leakage currents, which are relatively small). However, when an appropriate voltage is applied to the gate electrode, the channel region becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the FET as an active switch is degraded.

In contrast to a FET, which has a planar structure, a so-called FinFET device has a three-dimensional (3D) structure. More specifically, in a FinFET, a generally vertically positioned fin-shaped active area is formed and a gate electrode encloses both sides and an upper surface of the fin-shaped active area to form a tri-gate structure so as to use a channel having a three-dimensional structure instead of a planar structure. In some cases, an insulating cap layer, e.g., silicon nitride, is positioned at the top of the fin and the FinFET device only has a dual-gate structure. Unlike a planar FET, in a FinFET device, a channel is formed perpendicular to a surface of the semiconducting substrate so as to reduce the physical size of the semiconductor device. Also, in a FinFET, the junction capacitance at the drain region of the device is greatly reduced, which tends to reduce at least some short channel effects. When an appropriate voltage is applied to the gate electrode of a FinFET device, the surfaces (and the inner portion near the surface) of the fins, i.e., the substantially vertically oriented sidewalls and the top upper surface of the fin with inversion carriers, contributes to current conduction. In a FinFET device, the “channel-width” is approximately two times (2×) the vertical fin-height plus the width of the top surface of the fin, i.e., the fin width. Multiple fins can be formed in the same foot-print as that of a planar transistor device. Accordingly, for a given plot space (or foot-print), FinFETs tend to be able to generate significantly stronger drive currents than planar transistor devices. Additionally, the leakage current of FinFET devices after the device is turned “OFF” is significantly reduced as compared to the leakage current of planar FETs due to the superior gate electrostatic control of the “fin” channel on FinFET devices. In short, the 3D structure of a FinFET device is a superior MOSFET structure as compared to that of a planar FET, especially in the 20 nm CMOS technology node and beyond.

One process flow that is typically performed to form FinFET devices involves forming a plurality of trenches in the substrate to define the areas where STI regions will be formed and to define the initial structure of the fins. These trenches are typically formed in the substrate during the same process operation for processing simplicity. The trenches have a target depth that is sufficient for the needed fin height and deep enough to allow formation of an effective STI region. After the trenches are formed, a layer of insulating material, such as silicon dioxide, is formed so as to overfill the trenches. Thereafter, a chemical mechanical polishing (CMP) process is performed to planarize the upper surface of the insulating material with the top of the fins (or the top of a patterned hard mask). Thereafter, an etch-back process is performed to recess the layer of insulating material between the fins and thereby expose the upper portions of the fins, which corresponds to the final fin height of the fins.

In forming integrated circuits, it is necessary to electrically isolate certain device or circuits from one another. This is typically accomplished by forming one or more isolation structures, comprised of an insulating material. In modern-day devices, the isolation regions are typically so-called shallow trench isolation (STI) structures wherein one or more insulating materials are formed in a trench that has been formed in a semiconductor substrate. In the case of FinFET devices, the formation of isolation regions is a bit more complex as there needs to be a relatively deep device isolation region that separates the device, e.g., an N-type FinFET device, from other devices, such as a P-type FinFET device. Additionally, in the case of a multiple fin FinFET device, a shallow isolation region is formed between the adjacent fins of the device.

One typical process flow that is used in forming isolation regions on FinFET devices is as follows. Initially, an etching process is performed through a patterned hard mask layer, e.g., silicon nitride, to define a plurality of trenches. The trenches are typically formed to a depth that is equal to the desired depth of the deep isolation regions. The trenches define a plurality of fin structures as well. After the fins are initially formed, a patterned masking layer (e.g., photoresist) may be formed above the fins to permit removal of some of the fins and thereby laterally define regions where the deep isolation structures will be formed. Then, the masking layer is removed and the trenches are over-filled with an insulting material, such as silicon dioxide. Thereafter, a CMP process is performed that planarizes the upper surface of the layer of silicon dioxide with the upper surface of the hard mask layer. This effectively defines the deep isolation regions. In subsequent process operations, the deep isolation regions are masked while various processing activities are undertaken to form components or structures of the FinFET device.

The present disclosure is directed to various methods of forming isolation regions for 3D semiconductor devices, such as FinFET devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming isolation regions for 3D semiconductor devices, such as FinFET devices. In one example, the method disclosed herein includes forming a plurality of fin-formation trenches in a semiconductor substrate that define a plurality of spaced-apart fins, forming a patterned liner layer that covers a portion of the substrate positioned between the fins while exposing portions of the substrate positioned laterally outside of the patterned liner layer, and performing at least one etching process on the exposed portions of the substrate through the patterned liner layer to define an isolation trench in the substrate, wherein the isolation trench has a depth that is greater than a depth of the fin-formation trenches.

Another illustrative method disclosed herein involves forming a plurality of fin-formation trenches in a semiconductor substrate that define a plurality of spaced-apart fins, forming a patterned liner layer that covers a portion of the substrate positioned between the fins while exposing portions of the substrate positioned laterally outside of the patterned liner layer, wherein the patterned liner layer is comprised of a generally U-shaped liner portion positioned between the plurality of spaced-apart fins that covers the portion of the substrate, and performing at least one etching process on the exposed portions of the substrate through the patterned liner layer to define an isolation trench in the substrate, wherein the isolation trench has a depth that is greater than a depth of the fin-formation trenches. In this embodiment, the method further comprises the steps of, after forming the isolation trench, forming a layer of insulating material above the patterned liner layer so as to over-fill the isolation trench and performing at least one process operation to recess an upper surface of the layer of insulating material to a desired level, wherein recessing the layer of insulating material results in the definition of a deep isolation region positioned in the isolation trench and a shallow isolation region positioned above a portion of the generally U-shaped liner portion.

Yet another illustrative method disclosed herein involves forming a plurality of fin-formation trenches in a semiconductor substrate that define a plurality of spaced-apart fins, forming a patterned liner layer that covers a portion of the substrate positioned between the plurality of fins while exposing portions of the substrate positioned laterally outside of the patterned liner layer, wherein the patterned liner layer is comprised of a generally U-shaped liner portion positioned between the plurality of spaced-apart fins that covers the portion of the substrate, and performing at least one etching process on the exposed portions of the substrate through the patterned liner layer to define an isolation trench in the substrate, wherein the isolation trench has a depth that is greater than a depth of the fin-formation trenches. In this embodiment, the method includes the additional steps of, after forming the isolation trench, removing the patterned liner layer, forming a layer of insulating material that over-fills the isolation trench and the fin-forming trenches and performing at least one process operation to recess an upper surface of the layer of insulating material to a desired level, wherein recessing the layer of insulating material results in the definition of a deep isolation region positioned in the isolation trench and a shallow isolation region positioned between the plurality of fins.

### BRIEF DESCRIPTION OF THE DRAWINGS

The disclosure may be understood by reference to the following description taken in conjunction with the accompanying drawings, in which like reference numerals identify like elements, and in which:

FIG. 1 is a simplistic depiction of a FinFET device that is provided for reference purposes only;

FIGS. 2A-2H depict one illustrative method disclosed herein for forming isolation regions for a plurality of illustrative FinFET devices;

FIGS. 3A-3D depict another illustrative method disclosed herein for forming isolation regions for a plurality of illustrative FinFET devices; and

FIGS. 4A-4G depict various illustrative methods disclosed herein for forming isolation regions having at least differing depths in a semiconductor substrate.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In general, the present disclosure is directed to various methods of forming isolation regions for 3D semiconductor devices, such as FinFET devices. Moreover, as will be readily apparent to those skilled in the art upon a complete reading of the present application, the present method is applicable to a variety of devices, including, but not limited to, logic devices, memory devices, etc., and the methods disclosed herein may be employed to form N-type or P-type semiconductor devices. With reference to the attached figures, various illustrative embodiments of the methods and devices disclosed herein will now be described in more detail.

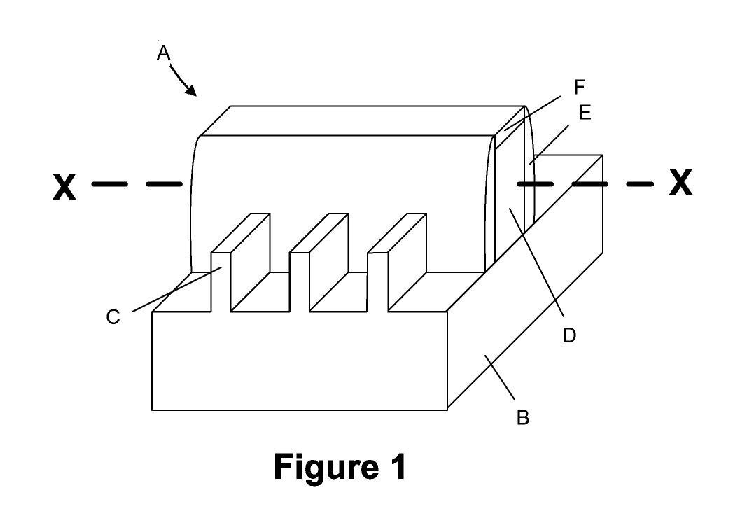

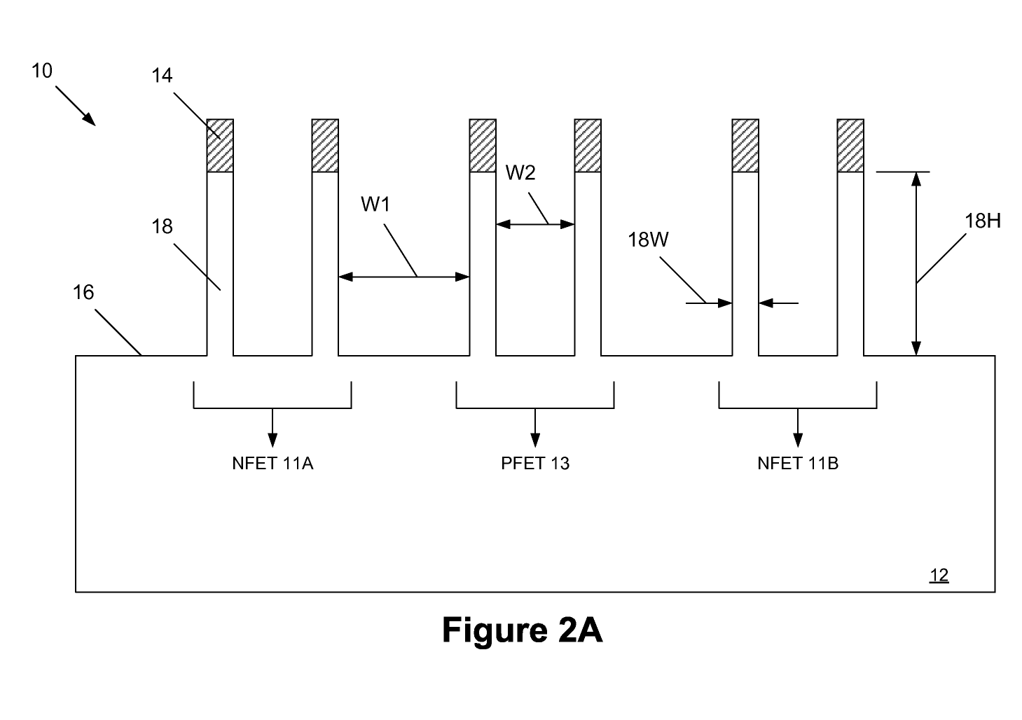

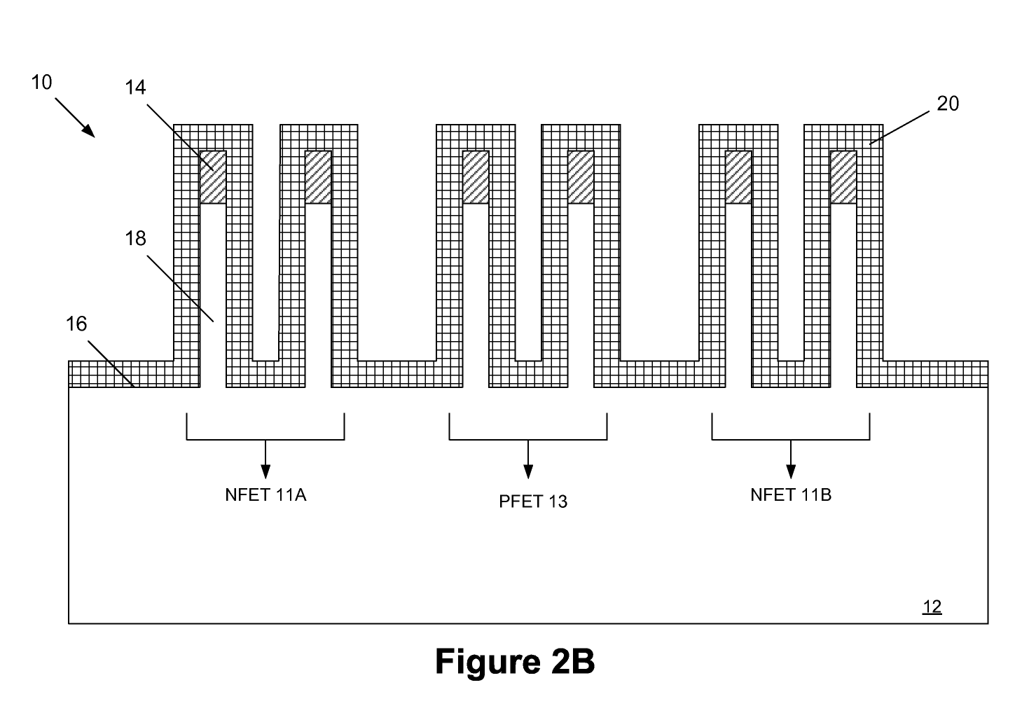

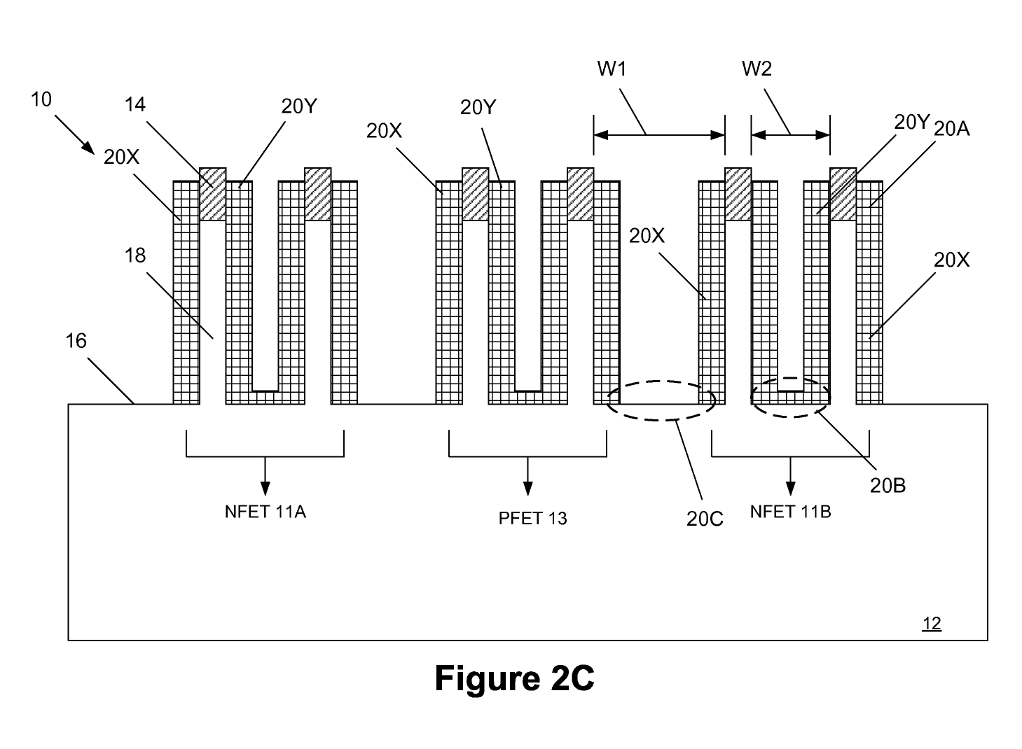

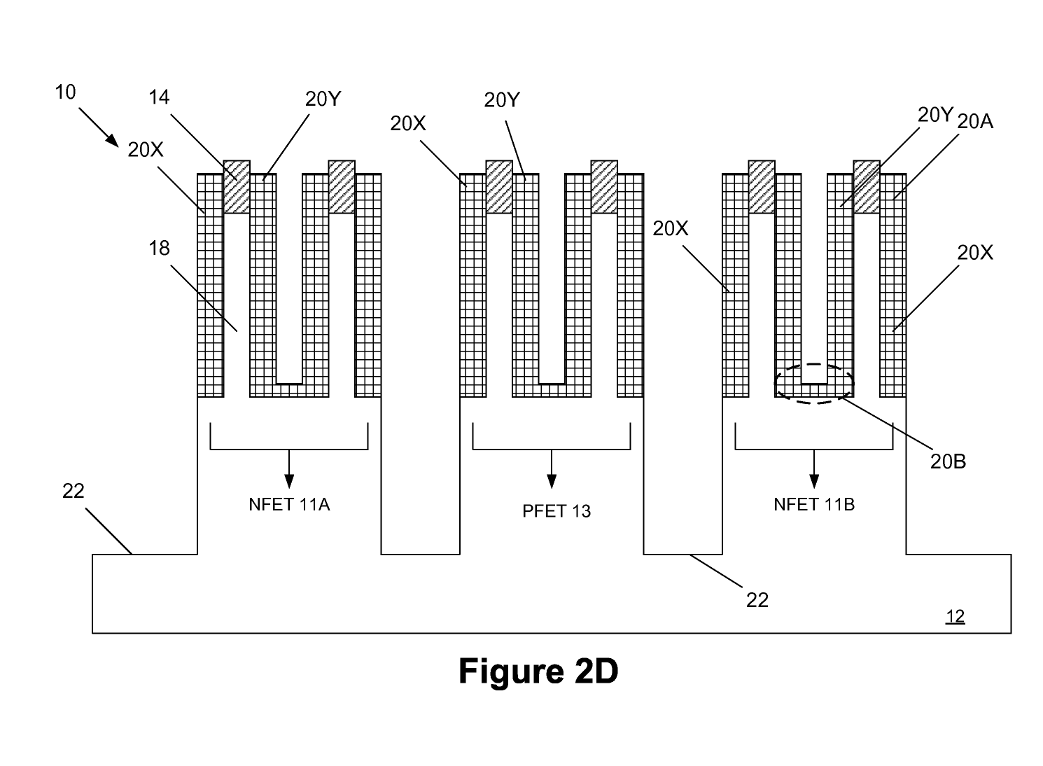

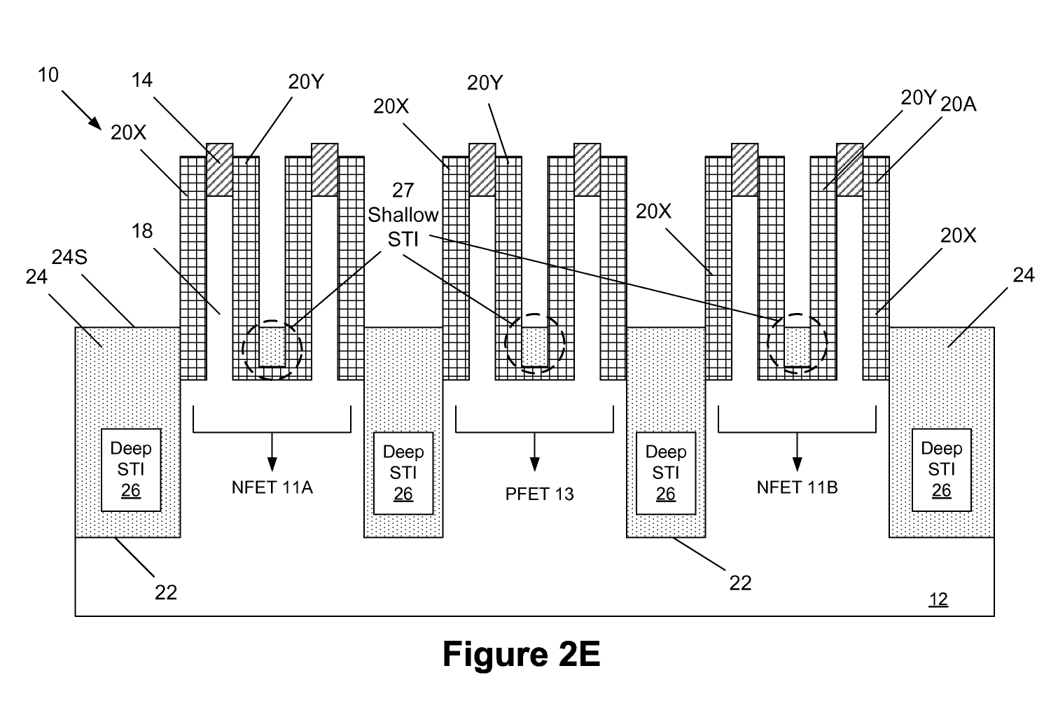

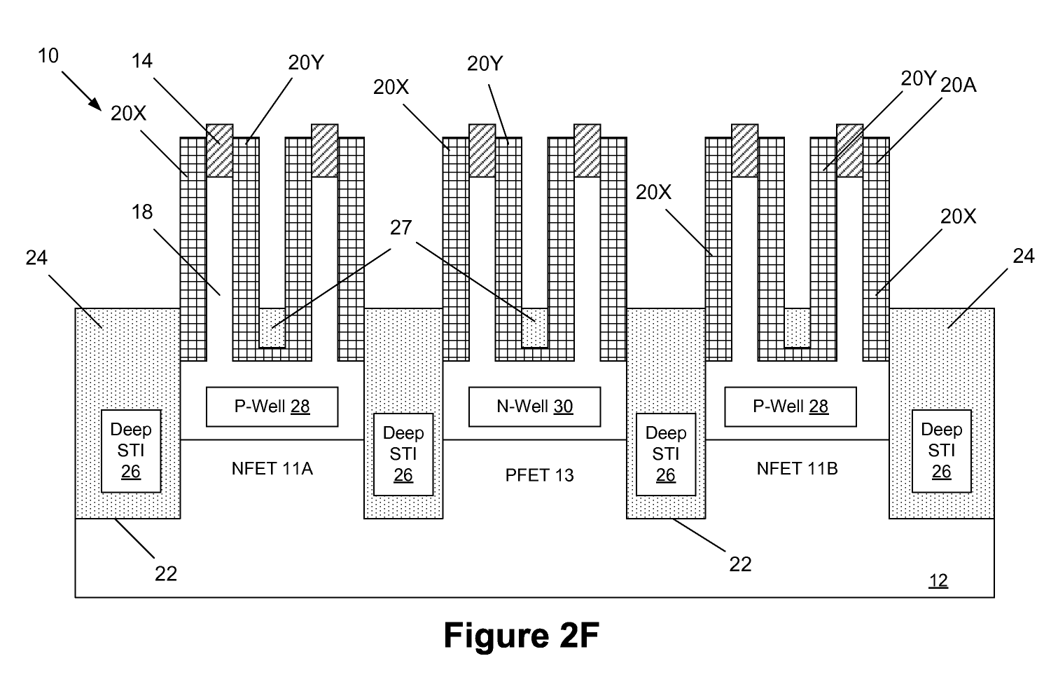

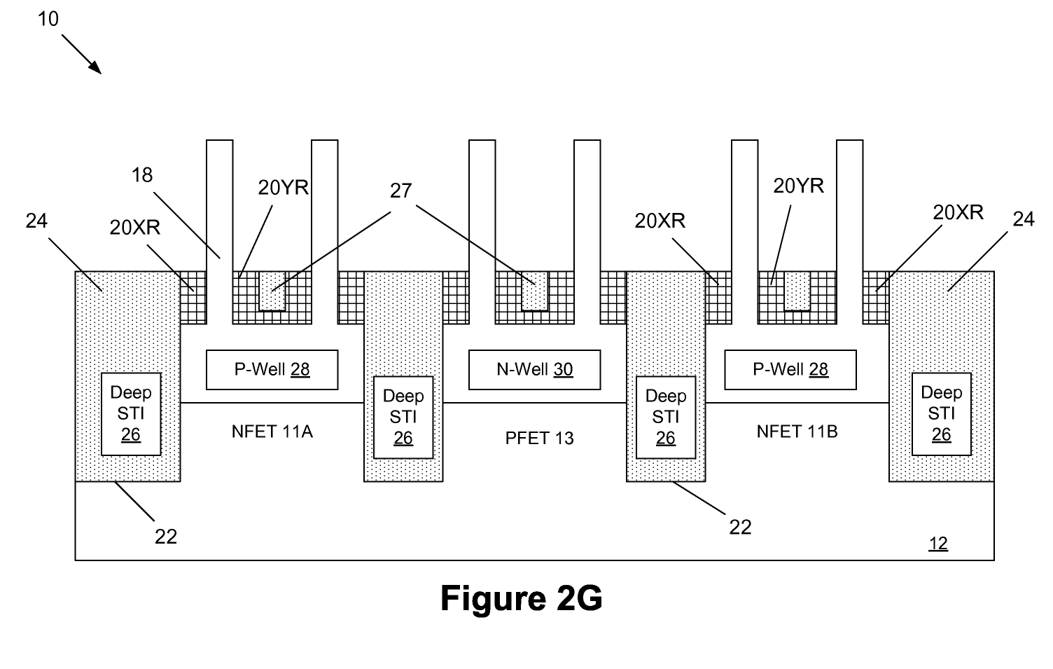

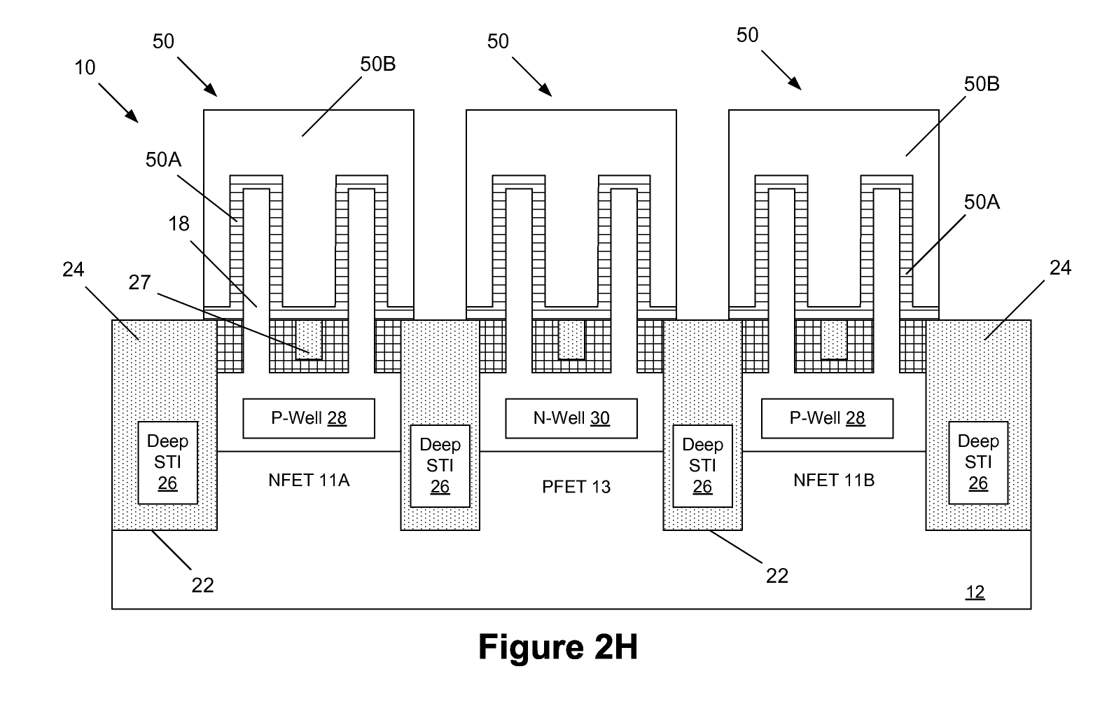

FIG. 1 is a perspective view of a reference FinFET semiconductor device “A” that is formed above a semiconductor substrate “B.” The device A includes a plurality of fins “C,” a gate electrode “D,” sidewall spacers “E” and a gate cap layer “F.” FIG. 1 depicts the locations where various cross-sectional views of the devices disclosed herein may be taken in the drawings discussed below. More specifically, the drawings in FIGS. 2A-2H, 3A-3D and 4A-4G below are cross-sectional views taken through the gate electrode D in a direction that is parallel to the long axis of the gate electrode D, i.e., in the gate width direction, indicated by the line “X-X”. In a conventional process flow, the portions of the fins C that are positioned in the source/drain regions may be increased in size or even merged together (not shown in FIG. 1) by performing one or more epitaxial growth processes. It should be understood that FIG. 1 is only provided to show the location of various cross-sectional views that may be depicted in the drawings below, and many aspects discussed below are not depicted in FIG. 1 so as to not overly complicate the device A depicted in FIG. 1.

FIGS. 2A-2H depict one illustrative method disclosed herein for forming isolation regions for a plurality of illustrative FinFET devices. FIG. 2A schematically depicts the novel integrated circuit product 10 that is comprised of two illustrative N-type FinFET devices 11A, 11B and an illustrative P-type FinFET device 13. At the point of fabrication depicted in FIG. 2A, a plurality of fin-formation trenches 16 have been formed in a bulk semiconducting substrate 12 by performing at least one etching process through a patterned hard mask layer 14, e.g., a patterned layer of silicon nitride. The etching process results in the formation of a plurality of spaced-apart fins 18. In the depicted example, each of the FinFET devices 11A, 11B and 13 are comprised of two illustrative fins 18. Of course, as well be appreciated by those skilled in the art, the FinFET devices 11A, 11B and 13 may have more than the depicted two fins 18. In the depicted example, the spacing between the fins 18, i.e., the dimension W2, is less than the spacing between adjacent devices, i.e., the dimension W1. In the depicted example, the spacing between the fins 18, i.e., W2, is approximately the same for all three FinFET devices 11A, 11B and 13, although such uniformity is not required to practice at least some aspects of the inventions disclosed herein. The magnitude of the dimensions W1 and W2 may vary depending upon the particular application. In one illustrative embodiment, the dimension W1 may fall within a range of about 50-200 nm, while the dimension W2 may fall within the range of about 10-50 nm. In some embodiments, the ratio W1/W2 should be greater than about 1.5.

The substrate 12 may have a variety of configurations, such as the depicted bulk substrate configuration. The substrate 12 may be made of silicon or it may be made of materials other than silicon. Thus, the terms “substrate” or “semiconducting substrate” should be understood to cover all semiconducting materials and all forms of such materials. Additionally, the overall size, shape and configuration of the trenches 16 and fins 18 may vary depending on the particular application. The depth and width of the trenches 16 may also vary depending upon the particular application. In one illustrative embodiment, based on current-day technology, the depth of the fin-formation trenches 16 may range from approximately 30-200 nm and the width of the fin-formation trenches 16 may range from about 10-50 nm. In some embodiments, the fins 18 may have a width 18W within the range of about 5-30 nm and a height 18H that corresponds to the depth of the fin-formation trenches 16. In the illustrative examples depicted in most of the attached drawings, the fin-formation trenches 16 and fins 18 are all depicted as having a uniform size and shape. However, as discussed more fully below, such uniformity in the size and shape of the fin-formation trenches 16 and the fins 18 is not required to practice at least some aspects of the inventions disclosed herein. In the attached figures, the fin-formation trenches 16 are depicted as having been formed by performing an anisotropic etching process that results in the fin-formation trenches 16 having a schematically depicted, generally rectangular configuration. In an actual real-world device, the sidewalls of the fin-formation trenches 16 may be somewhat inwardly tapered, although that configuration is not depicted in the attached drawings. In some cases, the fin-formation trenches 16 may have a reentrant profile (not shown) near the bottom of the fin-formation trenches 16. To the extent the fin-formation trenches 16 are formed by performing a wet etching process, the fin-formation trenches 16 may tend to have a more rounded configuration or non-linear configuration as compared to the generally rectangular configuration of the fin-formation trenches 16 that are formed by performing an anisotropic etching process. Thus, the size and configuration of the fin-formation trenches 16, and the manner in which they are made, as well as the general configuration of the fins 18, should not be considered a limitation of the present invention. For ease of disclosure, only the substantially rectangular fin-formation trenches 16 will be depicted in the subsequent drawings.

FIG. 2B depicts the product 10 after a conformal deposition process, e.g., a chemical vapor deposition (CVD) process, an atomic layer deposition (ALD) process, etc., has been performed to form a liner layer 20 on the product 10. More specifically, in the depicted example, the liner layer 20 is formed above the patterned hard mask layer 14, on the sidewalls of the fins 18 and in the fin-formation trenches 16. The thickness of the liner layer 20 may vary depending upon the particular application, e.g., it may have a thickness of about 3-10 nm. In general, the liner layer 20 may be made of a material that may be selectively etched relative to the insulating material that will be used to fill the remaining portions of the fin-formation trenches 16. For example, the liner layer 20 may be comprised of silicon nitride, silicon carbon nitride, silicon boron nitride, a doped nitride, silicon oxynitride, etc. In one particularly illustrative embodiment, both the patterned hard mask layer 14 and the liner layer 20 may be made of silicon nitride.

FIG. 2C show the product 10 after a timed, anisotropic etching process has been performed on the liner layer 20. The reference number 20A is used to depict the etched liner layer. In general, the etch rate in the above-described liner etch process is faster in wider spaces, i.e., the W1 spaces, than it is in narrower spaces, i.e., the W2 spaces. More specifically, in the wider spaces, the liner material may be cleared from the surface of the substrate 12, as indicated in the dashed region 20C, while, in the narrower spaces, portions of the liner material remain after the etching process is performed, as indicated in the dashed region 20B. The thickness of the remaining portions of the liner material within the region 20B may vary depending upon the application, e.g., in some cases, the thickness of the remaining portion of the liner material in the region 20B may be about 50% of the thickness of the initial liner layer 20. The slowing of the etch process in the narrower spaces may be referred to as a so-called capillary effect. Thus, the etched liner layer 20A is comprised of a plurality of schematically depicted sidewall spacers 20X that form in the wide spaces, e.g., the W1 spaces, and a plurality of schematically depicted “U” shaped portions 20Y positioned in the narrower spaces, e.g., the W2 spaces. Stated another way, in the depicted example, the U-shaped portions 20Y form between the fins 18 within a particular FinFET device, e.g., the PFET 13, while the sidewall spacers 20X form on the outer-most sidewalls of the outer fins of a particular device. The U-shaped portions 20Y cover a portion of the substrate 12. Stated another way, the etched or patterned liner layer 20A covers the portions of the substrate 12 positioned between the spaced-apart fins 18 while the portions of the substrate 12 positioned laterally outside of the patterned liner layer 20A, i.e., beyond the outermost spacers 20X, are exposed for further processing.

FIG. 2D show the product 10 after an etching process, such as a timed anisotropic etching process, has been performed through the patterned liner layer 20A on the exposed portions of the substrate 12 to define a plurality of isolation trenches 22 where deep isolation regions will be formed. The depth of the deep isolation trenches 22 may vary depending upon the particular application, e.g., 50-200 nm deep relative to the bottom of the fins 18. During this deep trench etch process, the remaining liner material at the bottom of the U-shaped portions 20Y, i.e., the material within the region 20B, prevents etching of the substrate 12 between adjacent fins 18.

FIG. 2E depicts the product 10 after several process operations have been performed. First, a layer of insulating material 24 was deposited above the patterned liner layer 20A so as to over-fill the isolation trenches 22 and the space within the U-shaped portions 20Y. Thereafter, a recess etching process was performed on the layer of insulating material 24 so as to recess its upper surface 24S to a desired level. In one illustrative example, the recessed surface 24S of the layer of insulating material 24 will effectively define the final fin height for the fins in the completed devices. The recess etching process also results in the creation of deep isolation regions 26 between the individual devices, and the creation of shallow isolation regions 27 within each device between adjacent fins 18 above the bottom portion of the generally U-shaped liner portions 20Y. The layer of insulating material 24 may be comprised of a variety of different materials, such as silicon dioxide, doped silicon dioxide (doped with carbon, boron or phosphorous), etc., and it may be formed by performing a variety of techniques, e.g., chemical vapor deposition (CVD), etc.

FIG. 2F depicts the product after P-wells 28 have been formed for the N-type devices 11A-B and after an N-well 30 has been formed for the P-type device 13. The wells 28, 30 may be formed using traditional masking and ion implantation techniques that are well known to those skilled in the art.

FIG. 2G depicts the product after one or more etching processes have been performed to remove the patterned hard mask 14 and portions of the patterned liner layer 20A selectively relative to the insulating material 24 and the fins 18. This etching process results in recessed sidewall spacers 20XR and recessed U-shaped portions 20YR and effectively defines the final fin height of the fins 18 for the devices 11A, 11B and 13. Initially, if desired, an optional oxide deglaze etching process may be performed to insure that all of the insulating material 24, e.g., silicon dioxide, is removed from the upper surfaces of the mask layer 14 and the patterned liner layer 20A prior to performing the above-described etching process.

FIG. 2H depicts the product after schematically depicted final gate structures 50 have been formed for the devices 11A, 11B and 13. In general, a final gate structure 50 is typically comprised of an illustrative gate insulation layer 50A and an illustrative gate electrode 50B. The final gate structure 50 may be formed using so-called “gate-first” or “replacement-gate” (“gate-last”) techniques. An illustrative gate cap layer (not shown) may also be formed above the illustrative gate electrode 50B. The gate insulation layer 50A may be comprised of a variety of different materials, such as, for example, silicon dioxide, a so-called high-k (k greater than 10) insulation material (where k is the relative dielectric constant), etc. The thickness of the gate insulation layer 50A may also vary depending upon the particular application, e.g., it may have a thickness of about 1-2 nm. Similarly, the gate electrode 50B may also be of a variety of conductive materials, such as polysilicon or amorphous silicon, or it may be comprised of one or more metal layers that act as the gate electrode 50B. Additionally work-function adjusting metals may be formed as part of the gate structure in some applications. As will be recognized by those skilled in the art after a complete reading of the present application, the gate structure 50 depicted in the drawings, i.e., the gate insulation layer 50A and the gate electrode 50B, is intended to be representative in nature. That is, the gate structure 50 may be comprised of a variety of different materials and it may have a variety of configurations. Of course, depending upon the particular application, the materials of construction for the gate structure 50 of the N-type FinFET devices may be different than the materials of construction for the gate structure 50 of the P-type devices. In one illustrative embodiment, a deposition process may be performed to form the depicted gate insulation layer 50A comprised of a high-k insulating material. Thereafter, one or more metal layers (that will become the gate electrode 50B) and a gate cap layer material (not shown), e.g., silicon nitride, may be deposited above the device 10. At this point, traditional manufacturing techniques may be performed to complete the manufacture of the product 10. For example, sidewall spacers (not shown) comprised of, for example, silicon nitride, may be formed adjacent the final gate structures 50. After the spacers are formed, if desired, an epitaxial growth process may be performed to form additional semiconducting material (not shown) on the portions of the fins 18 positioned outside of the spacers. Additional contacts and metallization layers may then be formed above the FinFET devices 11A, 11B and 13 using traditional techniques.

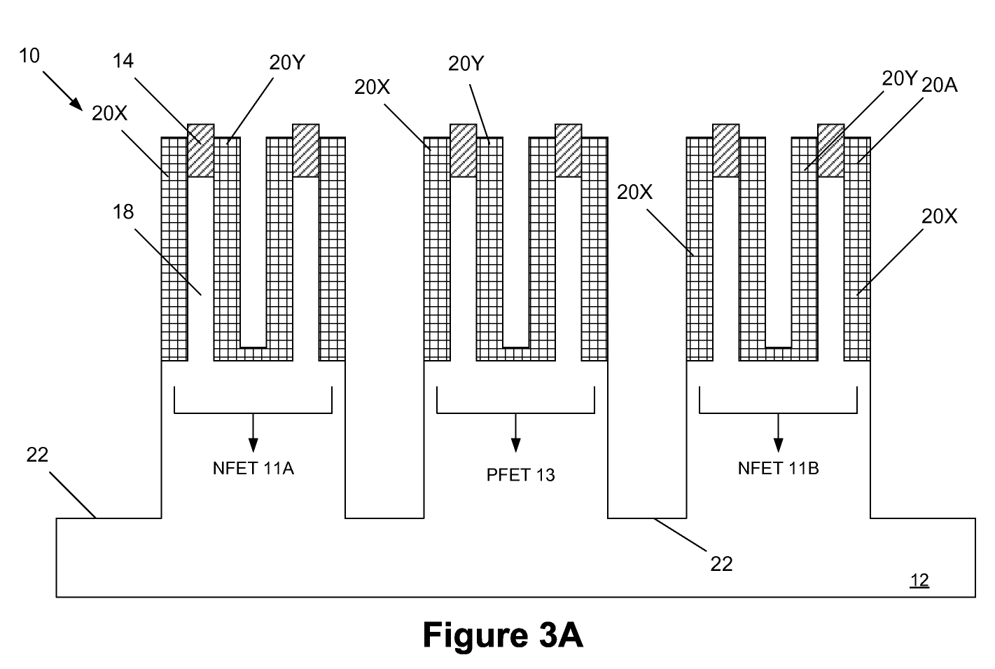

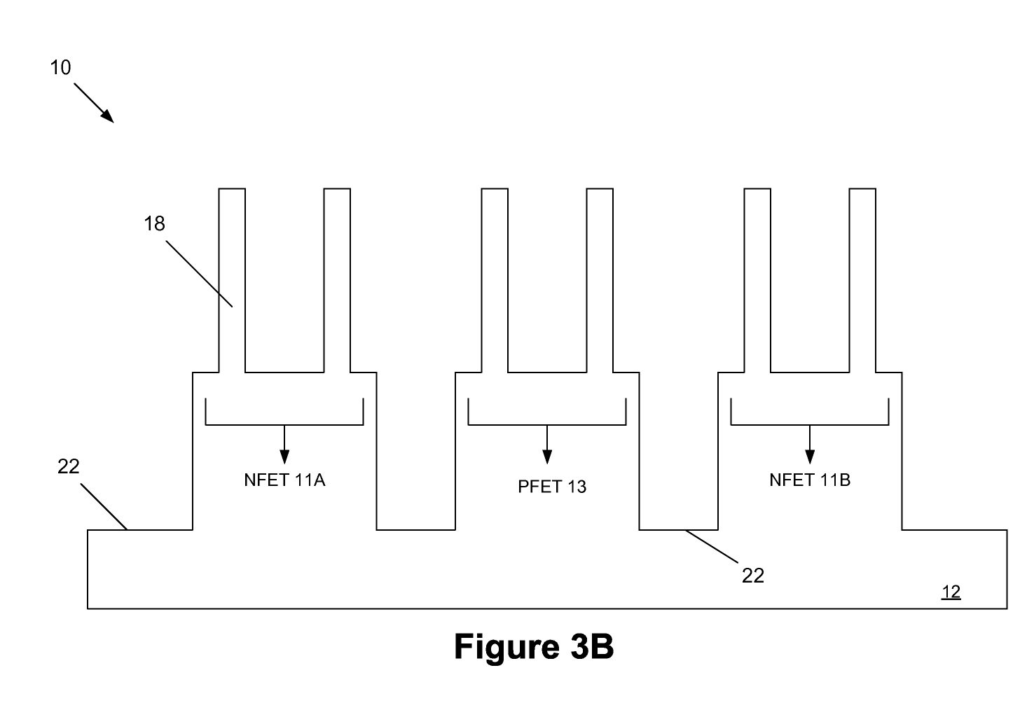

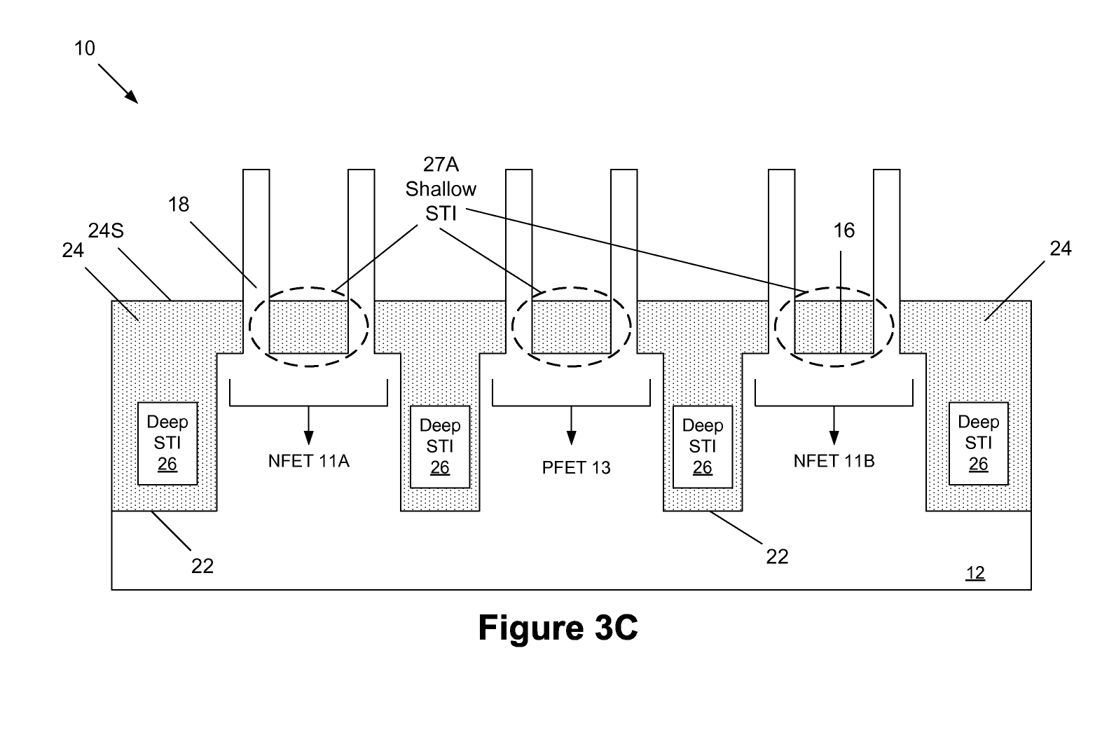

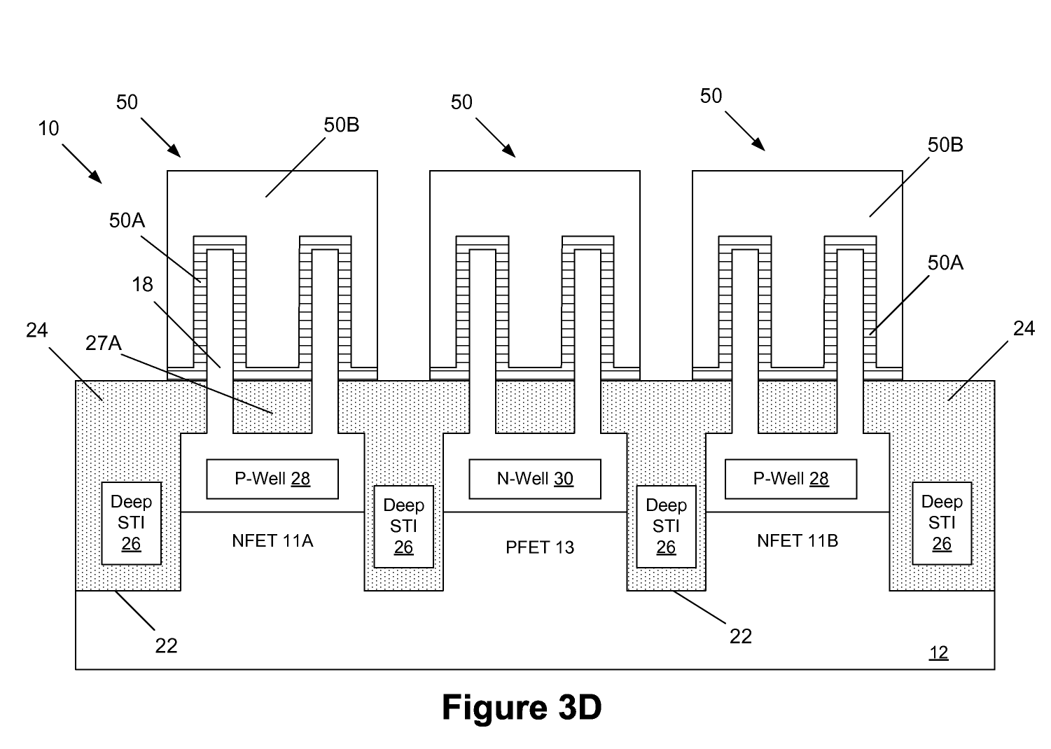

FIGS. 3A-3D depict another illustrative method disclosed herein for forming isolation regions for a plurality of illustrative FinFET devices. FIG. 3A depicts the product at a point of fabrication that corresponds to that depicted in FIG. 2D, i.e., after the deep isolation trenches 22 have been formed in the substrate 12. FIG. 3B depicts the product 10 after one or more etching processes were performed to remove the patterned hard mask 14 and the patterned liner layer 20A selectively relative to the substrate 12.

FIG. 3C depicts the product 10 after several process operations have been performed. First, the above-described layer of insulating material 24 was deposited so as to overfill the isolation trenches 22 and the fin-formation trenches 16, i.e., to fill the space between the fins 18. Thereafter, a recess etching process was performed on the layer of insulating material 24 so as to recess its upper surface 24S to the desired level. If desired, after depositing the layer of insulating material 24, a CMP process may be performed on the layer of insulating material 24 to planarize its upper surface with the upper surface of the fins 18 prior to performing the above-described recess etching process on the layer of insulating material 24. As before, the recess etching process also results in the creation of deep isolation regions 26 between the individual devices, and the creation of shallow isolation regions 27 within each device between adjacent fins 18. In this embodiment, the U-shaped portions 20Y and the sidewall spacers 20X are not present as they were removed prior to forming the layer of insulating material 24. FIG. 3D depicts the product after the above-described wells 28, 30 and gate structures 50 are formed for the individual FinFET devices 11A, 11B and 13.

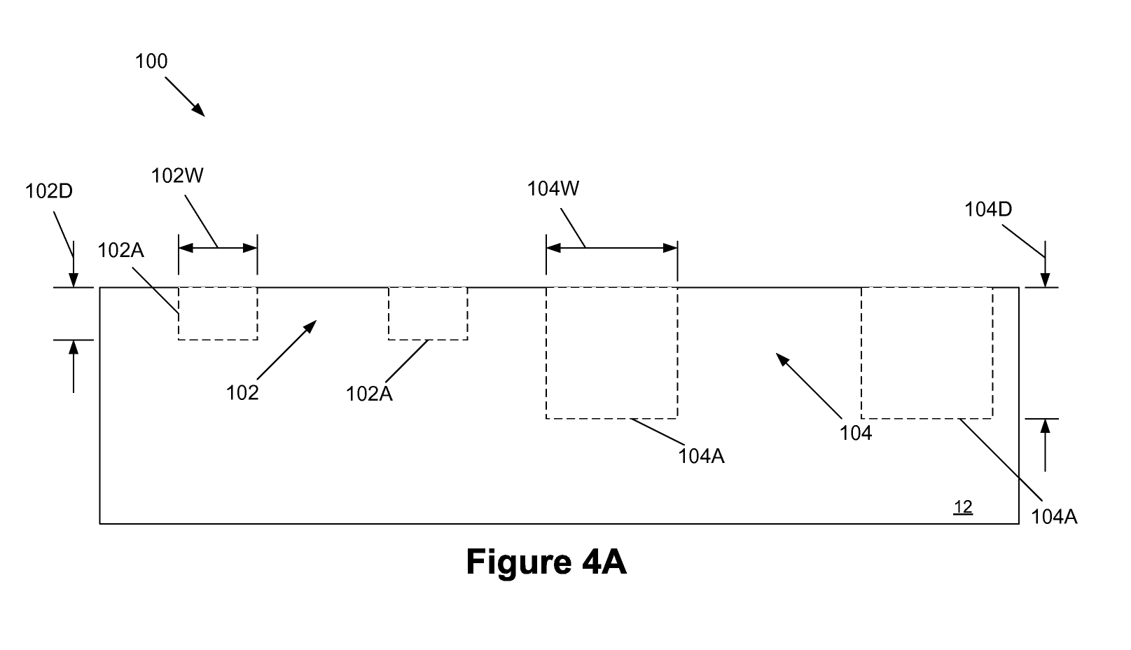

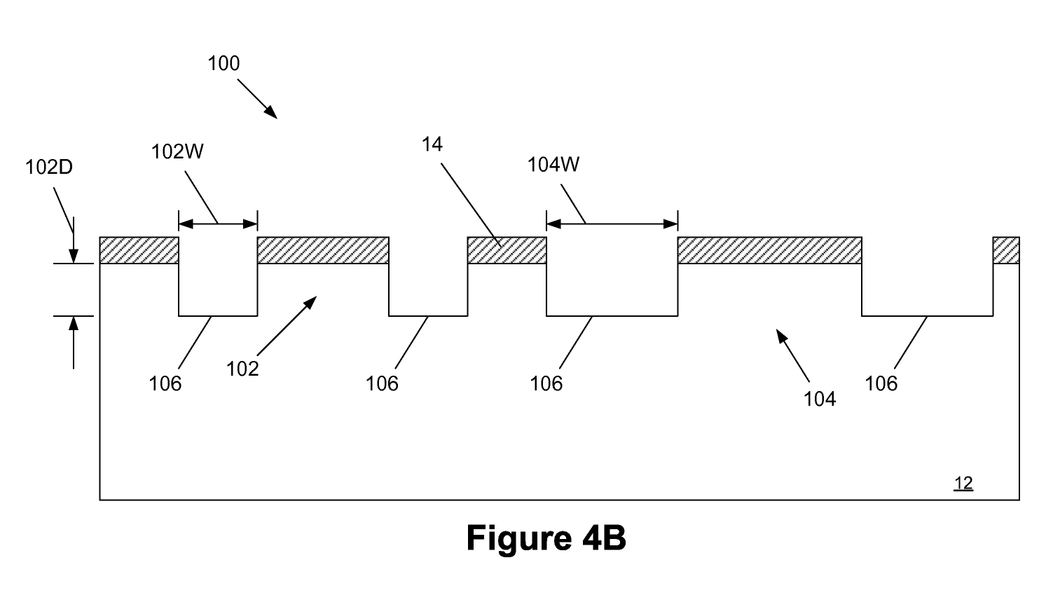

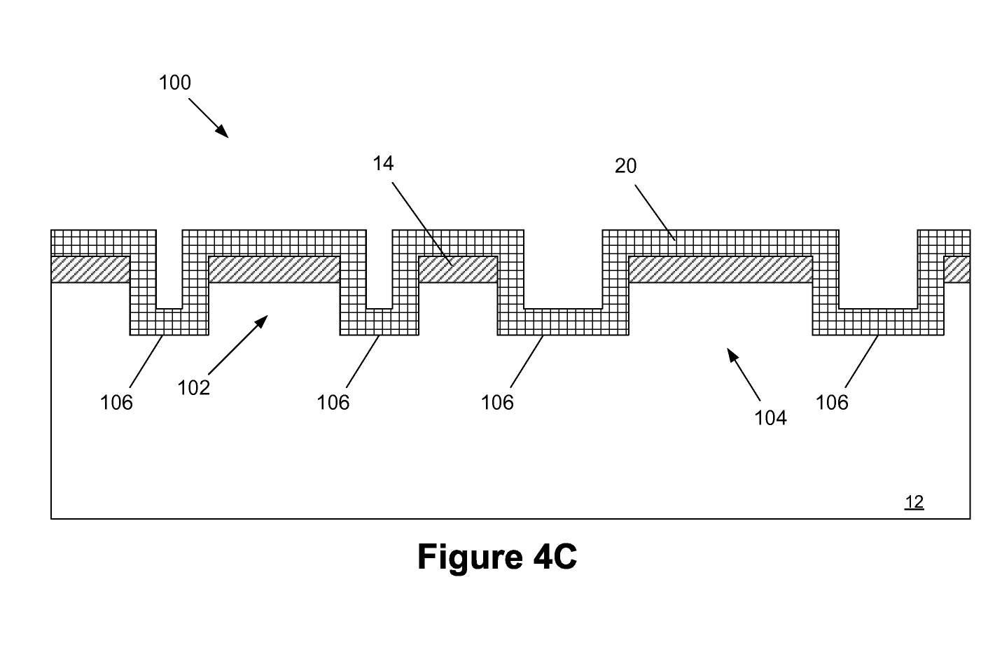

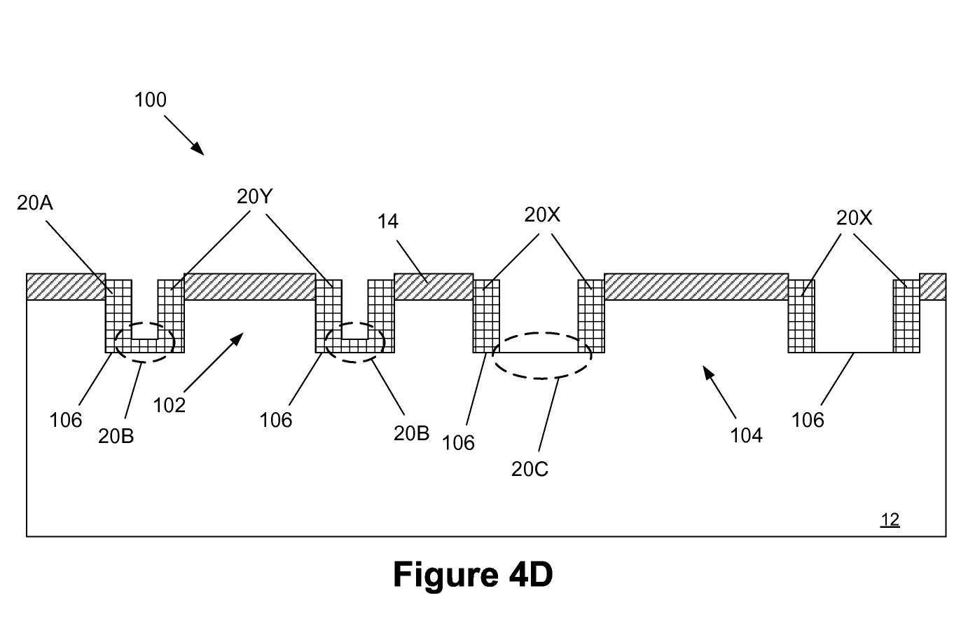

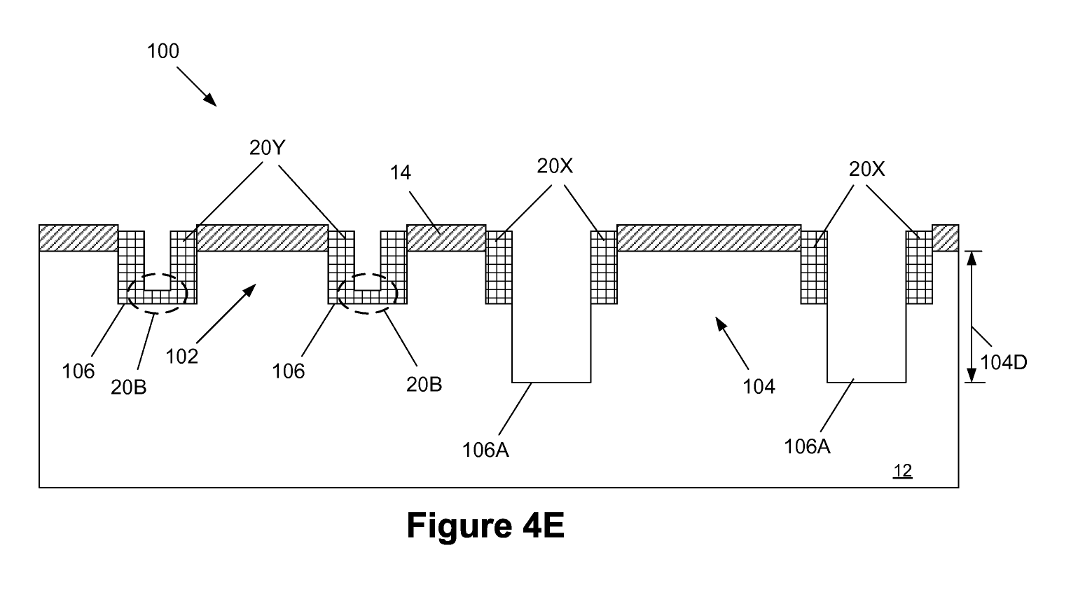

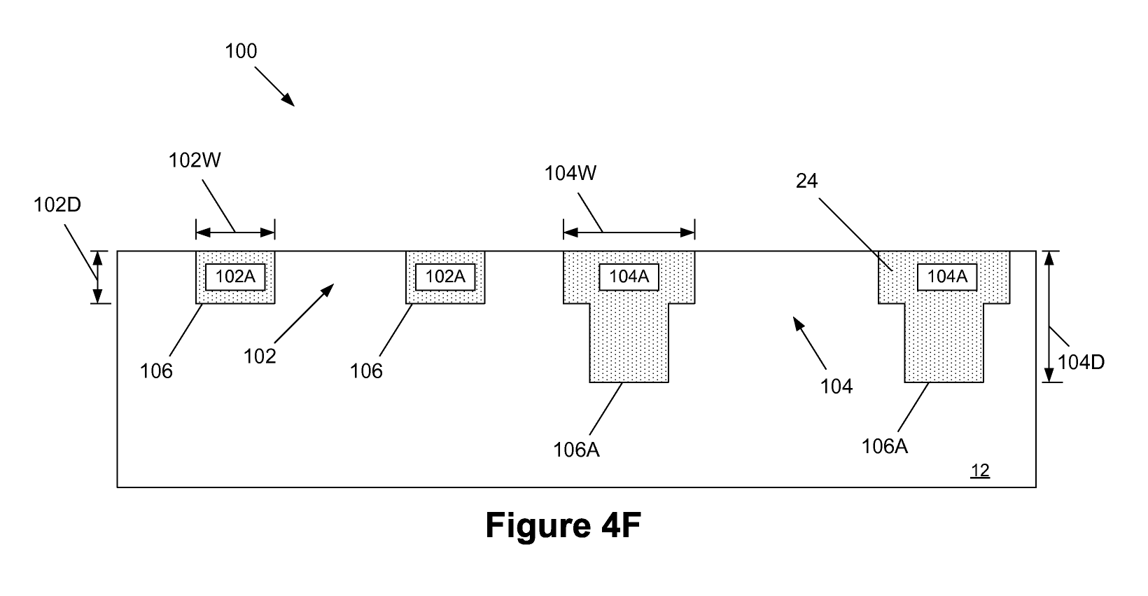

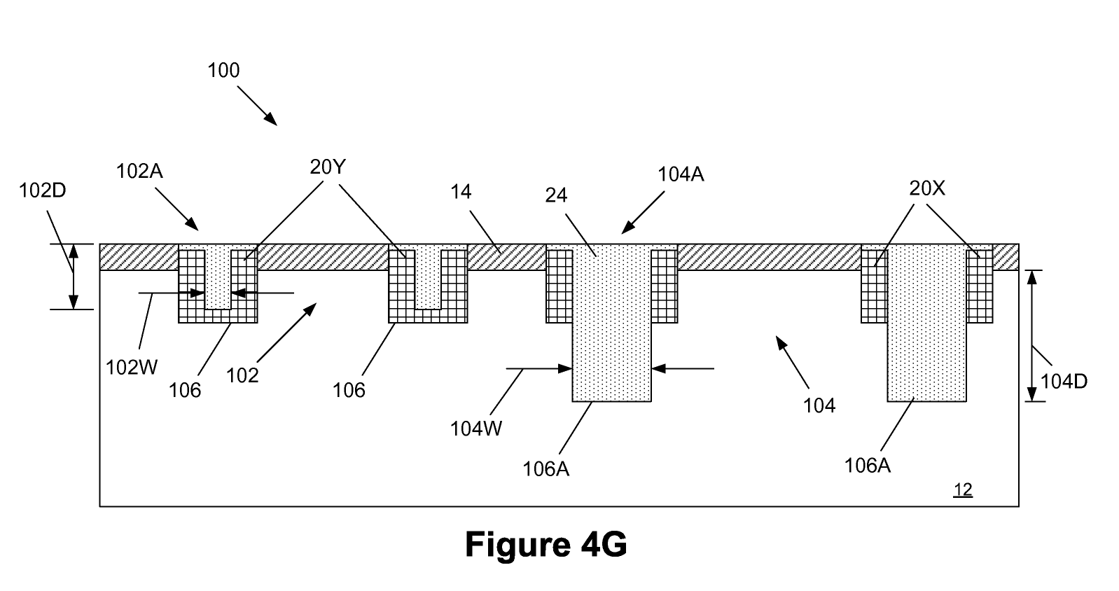

FIGS. 4A-4G depict various illustrative methods disclosed herein for forming isolation regions having at least differing depths in a semiconductor substrate. FIG. 4A depicts an illustrative integrated circuit product 100 wherein it is desired to form isolation regions having differing depths and perhaps differing widths in a semiconductor substrate 12. Such differing isolation structures may be useful on an integrated circuit product for a variety of different regions, e.g., for isolating individual semiconductor devices or regions of the substrate that operate at different voltage levels.

More specifically, as shown in FIG. 4A, the product 100 may have a first active region 102 and a second active region 104. The first active region 102 will be defined by a relatively shallow isolation region 102A (shown in dashed lines in FIG. 4A as it has not yet been formed), while the second active region 104 will be defined by a relatively deeper isolation region 104A (again shown in dashed lines). In the depicted example, the final depth 104D of the deep isolation region 104A is greater than the final depth 102D of the shallow isolation region 102A. In some embodiments, the width 104W of the deep isolation region 104A (at the upper surface) may also be greater that the width 102W of the shallow isolation region 102A (at the upper surface). The absolute value of the final depth and final width of the isolation regions 102A, 104A may vary depending upon the particular application. For example, the upper surface width 102W may fall within a range of about 20-100 nm, the final depth 102D may fall within a range of about 30-50 nm, the upper surface width 104W may fall within a range of about 100-1000 nm, and the final depth 104D may fall within a range of about 50-100 nm. In some embodiments the ratio 104D/102D may be greater than about 2, and the ratio 104W/102W may be greater than about 1.5.

At the point of fabrication depicted in FIG. 4B, a plurality of initial trenches 106 have been formed in the substrate 12 by performing at least one etching process through the above-described patterned hard mask layer 14. The initial trenches 106 surround both the first and second active regions 102, 104 and they are formed to a depth that corresponds approximately to the desired final depth 102D of the shallow isolation region 102A. The trench 106 that surrounds the first active region 102 is formed to the desired upper surface width 102W of the shallow isolation region 102A. In one embodiment, the trench 106 that surrounds the second active region 104 is formed to the desired upper surface width 104W of the deep isolation region 104A.

FIG. 4C depicts the product 100 after a conformal deposition process, e.g., a chemical vapor deposition (CVD) process, an atomic layer deposition (ALD) process, etc., was performed to form the above-described liner layer 20 on the product 100 and in the initial trenches 106.

FIG. 4D shows the product 100 after an anisotropic etching process was performed on the liner layer 20. The reference number 20A is used to depict the patterned liner layer 20A. The patterned liner layer 20A is comprised of a plurality of schematically depicted sidewall spacers 20X that form in the wide spaces, e.g., in the wider trenches 106 for the second active region 104, and a plurality of schematically depicted “U” shaped portions 20Y positioned in the narrower spaces, e.g., in the narrower trenches 106 for the first active region 102. In general, as described above, the etch rate in the liner etch process is faster in wider spaces, i.e., the space between the sidewall spacers 20X, than it is in narrower spaces, i.e., the space between the upstanding (vertically oriented) portions of the U-shaped portions 20Y.

More specifically, in the wider spaces, the liner material may be cleared from the surface of the substrate 12, as indicated in the dashed region 20C, while, in the narrower spaces, portions of the liner material remain after the etching process is performed, as depicted in the dashed region 20B. That is, the patterned liner layer 20A is formed in the trenches 106 such that it covers the bottom surface of the trench 106 where the shallow isolation region 102A will be formed but exposes a portion of the bottom surface of the trench 106, i.e., the substrate, where the deep isolation region 104A will be formed.

FIG. 4E show the product 100 after an etching process, such as a timed anisotropic etching process has been performed through the patterned liner layer 20A on the substrate 12 to define a deep isolation trench 106A. The depth of the deep isolation trench 106A corresponds approximately to the final desired depth 104D of the deep isolation region 104A. During this deep trench etch process, the remaining liner material at the bottom of the U-shaped portions 20Y, i.e., the material within the region 20B, prevents etching of the substrate 12. Stated another way, the U-shaped portions 20Y of the patterned liner layer 20A cover a portion of the substrate 12 within the narrower trenches 106 for the shallow isolation region 102A, while the portions of the substrate 12 positioned laterally between the sidewalls spacers 20X formed in the wider trenches 106 that were formed for deeper isolation region 104A are exposed for further processing.

FIG. 4F depicts the product 100 after several process operations have been performed. First, one or more etching processes were performed to remove the patterned hard mask 14 and portions of the patterned liner layer 20A selectively relative to the substrate 12. In some cases, the hard mask layer 14 may be left in place. Thereafter, the above-described layer of insulating material 24 was deposited so as to overfill the trenches 106, 106A. Then, a process operation, such as a CMP process, was performed on the layer of insulating material 24 to planarize its upper surface with the upper surface of the substrate 12 (or the hard mask 14 if it remains in position). These operations result in the formation of the shallow isolation region 102A and the deep isolation region 104A.

FIG. 4G depicts an alternative process flow wherein the patterned liner layer 20A is left on the product 100. In this process flow, the above-described steps through FIG. 4E are the same. Thereafter, as shown in FIG. 4G, the above-described layer of insulating material 24 was deposited so as to overfill the trenches 106, 106A that contain the remaining portions of the patterned liner layer 20A. Then, a CMP process was performed on the layer of insulating material 24 to planarize its upper surface with the upper surface of the hard mask 14. These operations result in the formation of the shallow isolation region 102A and the deep isolation region 104A. Note that, in this example, the upper surface widths, 102W, 104W of the isolation regions are effectively reduced by the thickness of the portions of the patterned liner layer 20A remaining in the initial trenches 106. Also note that the final depth 102D of the shallow isolation region 102A is reduced by the amount of material of the liner at the bottom of the generally U-shaped portions 20Y positioned in the trench 106 that surrounds the active region 102. That is, in this embodiment, the initial trenches 106 are formed to a depth that is slightly greater than the final depth for the shallow isolation region 102A (by the thickness of the bottom portion of the U-shaped segment of the patterned liner layer 20A positioned within the trench 106 formed for the shallow isolation region 102A).

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a FinFET device, comprising:
forming a plurality of fin-formation trenches in a semiconductor substrate, said fin-formation trenches defining a plurality of spaced-apart fins;
forming a patterned liner layer that covers a portion of said substrate positioned between said plurality of fins while exposing portions of said substrate positioned laterally outside of said patterned liner layer; and
performing at least one etching process on said exposed portions of said substrate through said patterned liner layer to define an isolation trench in said substrate, wherein said isolation trench has a depth that is greater than a depth of said fin-formation trenches.

2. The method of claim 1, wherein said patterned liner layer is comprised of silicon nitride.

3. The method of claim 1, further comprising, after forming said isolation trench, forming a layer of insulating material above said patterned liner layer so as to over-fill said isolation trench.

4. The method of claim 3, further comprising performing at least one process operation to recess an upper surface of said layer of insulating material to a desired level, wherein recessing said layer of insulating material results in the definition of a deep isolation region positioned in said isolation trench and a shallow isolation region positioned above a portion of said patterned liner layer between said plurality of fins.

5. The method of claim 4, further comprising performing at least one etching process to remove portions of said patterned liner layer selectively relative to said plurality of fins and to said layer of insulating material and thereby expose at least portions of said plurality of fins.

6. The method of claim 5, further comprising forming a gate structure around at least a portion of said exposed portions of said plurality of fins.

7. The method of claim 3, wherein said patterned liner layer is comprised of silicon nitride and said layer of insulating material is comprised of silicon dioxide.

8. The method of claim 3, wherein performing said at least one process operation comprises performing at least one etching process to recess said upper surface of said layer of insulating material to said desired level.

9. The method of claim 1, further comprising removing said patterned liner layer.

10. The method of claim 9, further comprising, after removing said patterned liner layer, forming a layer of insulating material that over-fills said isolation trench and said plurality of fin-forming trenches.

11. The method of claim 10, further comprising performing at least one process operation to recess an upper surface of said layer of insulating material to a desired level, wherein recessing said layer of insulating material results in the definition of a deep isolation region positioned in said isolation trench and a shallow isolation region positioned between said plurality of fins.

12. The method of claim 11, further comprising forming a gate structure around at least a portion of said plurality of fins.

13. A method of forming a FinFET device, comprising:
forming a plurality of fin-formation trenches in a semiconductor substrate, said fin-formation trenches defining a plurality of spaced-apart fins;
forming a patterned liner layer that covers a portion of said substrate positioned between said plurality of fins while exposing portions of said substrate positioned laterally outside of said patterned liner layer, wherein said patterned liner layer is comprised of a generally U-shaped liner portion positioned between said plurality of spaced-apart fins that covers said portion of said substrate;
performing at least one etching process on said exposed portions of said substrate through said patterned liner layer to define an isolation trench in said substrate, wherein said isolation trench has a depth that is greater than a depth of said fin-formation trenches;
after forming said isolation trench, forming a layer of insulating material above said patterned liner layer so as to over-fill said isolation trench; and
performing at least one process operation to recess an upper surface of said layer of insulating material to a desired level, wherein recessing said layer of insulating material results in the definition of a deep isolation region positioned in said isolation trench and a shallow isolation region positioned above a portion of said generally U-shaped liner portion.

14. The method of claim 13, further comprising performing at least one etching process to remove portions of said patterned liner layer selectively relative to said plurality of fins and to said layer of insulating material and thereby expose at least portions of said plurality of fins.

15. The method of claim 13, further comprising forming a gate structure around at least a portion of said exposed portions of said plurality of fins.

16. The method of claim 13, wherein said patterned liner layer is comprised of silicon nitride and said layer of insulating material is comprised of silicon dioxide.

17. A method of forming a FinFET device, comprising:
forming a plurality of fin-formation trenches in a semiconductor substrate, said fin-formation trenches defining a plurality of spaced-apart fins;
forming a patterned liner layer that covers a portion of said substrate positioned between said plurality of fins while exposing portions of said substrate positioned laterally outside of said patterned liner layer, wherein said patterned liner layer is comprised of a generally U-shaped liner portion positioned between said plurality of spaced-apart fins that covers said portion of said substrate;
performing at least one etching process on said exposed portions of said substrate through said patterned liner layer to define an isolation trench in said substrate, wherein said isolation trench has a depth that is greater than a depth of said fin-formation trenches;
after forming said isolation trench, removing said patterned liner layer;
after removing said patterned liner layer, forming a layer of insulating material that over-fills said isolation trench and said plurality of fin-forming trenches; and
performing at least one process operation to recess an upper surface of said layer of insulating material to a desired level, wherein recessing said layer of insulating material results in the definition of a deep isolation region positioned in said isolation trench and a shallow isolation region positioned between said plurality of fins.

18. The method of claim 17, further comprising forming a gate structure around at least a portion of said plurality of fins.

19. The method of claim 17, wherein said patterned liner layer is comprised of silicon nitride and said layer of insulating material is comprised of silicon dioxide.

20. A method of forming first and second isolation structures having first and second final depths, respectively, in a semiconductor substrate, said second final depth being greater than said first final depth, the method comprising:
forming first and second trenches in said substrate around first and second active regions, respectively, said first and second trenches having a common depth;
forming a patterned liner layer in said first and second trenches that covers a bottom surface of said first trench and exposes at least a portion of a bottom surface of said second trench; and
performing at least one etching process through said patterned liner layer on said exposed portion of said bottom surface of said second trench to define a third trench having a depth that is greater than said common depth and corresponds to said final depth of said second isolation structure.

21. The method of claim 20, wherein said patterned liner layer is comprised of a generally U-shaped portion positioned on said bottom surface of said first trench and sidewall spacers positioned on sidewalls of said second trench.

22. The method of claim 20, wherein said first and second trenches have first and second widths, respectively, said second width being greater than said first width.

23. The method of claim 20, wherein said common depth corresponds to said final depth of said first isolation structure.

24. The method of claim 20, further comprising:
forming a layer of insulating material that over-fills portions of said first, second and third trenches not occupied by said patterned liner layer; and
performing at least one process operation to remove excess amounts of said layer of insulating material so as to thereby define said first and second isolation regions.

25. The method of claim 20, further comprising:
removing said patterned liner layer;
forming a layer of insulating material that over-fills said first, second and third trenches; and
performing at least one process operation to remove excess amounts of said layer of insulating material so as to thereby define said first and second isolation regions.

26. A method of forming first and second isolation structures having first and second final depths, respectively, in a semiconductor substrate, said second final depth being greater than said first final depth, the method comprising:
forming first and second trenches in said substrate around first and second active regions, respectively, said first and second trenches having a common depth that corresponds to said final depth of said first isolation structure;
forming a patterned liner layer in said first and second trenches that covers a bottom surface of said first trench and exposes at least a portion of a bottom surface of said second trench;
performing at least one etching process through said patterned liner layer on said exposed portion of said bottom surface of said second trench to define a third trench having a depth that corresponds to said final depth of said second isolation structure;
removing said patterned liner layer;
after removing said patterned liner layer, forming a layer of insulating material that over-fills said first, second and third trenches; and
performing at least one process operation to remove excess amounts of said layer of insulating material so as to thereby define said first and second isolation regions.

27. A method of forming first and second isolation structures having first and second final depths, respectively, in a semiconductor substrate, said second final depth being greater than said first final depth, the method comprising:
forming first and second trenches in said substrate around first and second active regions, respectively, said first and second trenches having a common depth;
forming a patterned liner layer in said first and second trenches that covers a bottom surface of said first trench and exposes at least a portion of a bottom surface of said second trench;
performing at least one etching process through said patterned liner layer on said exposed portion of said bottom surface of said second trench to define a third trench having a depth that corresponds to said final depth of said second isolation structure;
forming a layer of insulating material above said patterned liner layer, said layer of insulating material over-filling portions of said first, second and third trenches not occupied by said patterned liner layer; and
performing at least one process operation to remove excess amounts of said layer of insulating material so as to thereby define said first and second isolation regions.

28. The method of claim 27, wherein said patterned liner layer is comprised of a generally U-shaped portion positioned on said bottom surface of said first trench and sidewall spacers positioned on sidewalls of said second trench.

29. The method of claim 27, wherein said first and second trenches have first and second widths, respectively, said second width being greater than said first width.

30. The method of claim 28, wherein said first isolation region is at least partially positioned within said generally U-shaped portion of said patterned liner layer.

31. The method of claim 27 wherein said common depth is greater than said final depth of said first isolation structure.
